(19) United States
(12) Patent Application Publication
(10) Pub. No.: US 2024/0404999 A1
(43) Pub. Date: Dec. 5, 2024

(54) DISPLAY PANEL, TILED DISPLAY PANEL AND MANUFACTURING METHOD OF DISPLAY PANEL

(71) Applicant: Guangzhou China Star Optoelectronics Semiconductor Display Technology Co., Ltd., Guangzhou (CN)

(72) Inventor: Jubin LI, Guangzhou (CN)

(21) Appl. No.: 18/522,478

(22) Filed: Nov. 29, 2023

(30) Foreign Application Priority Data
May 31, 2023 (CN) 202310639543.7

(51) Int. Cl. H01L 25/075; H01L 33/44; H01L 33/54; H01L 33/62

(52) U.S. Cl. CPC H01L 25/0753; H01L 33/44; H01L 33/54; H01L 33/62; H01L 2933/0025; H01L 2933/005; H01L 2933/0066

(57) ABSTRACT

A display panel, a tiled display panel and a manufacturing method of display panel are provided. The display panel includes a substrate; a light-shielding layer disposed on the substrate and provided with a plurality of through-holes; a transparent insulation layer including transparent portions arranged in the through-holes respectively; a light-emitting layer disposed on the transparent insulation layer, wherein the light-emitting layer includes a plurality of light-emitting diode (LED) chips are disposed to the plurality of through-holes in a one-to-one correspondence, and a light-emitting surface the LED chip faces to the transparent portion; a device array layer disposed on the light-shielding layer and including a driver and a plurality of metal wirings used to connect the LED chips with the driver; and a sealing layer disposed on the substrate and encapsulating the light-shielding layer, the transparent insulation layer, the light-emitting layer, and the device array layer.

### CROSS-REFERENCE TO RELATED APPLICATION

This application claims priority to Chinese Patent Application No. 202310639543.7, filed on May 31, 2023, the disclosure of which is incorporated herein by reference in its entirety.

### TECHNICAL FIELD

The present disclosure relates to the field of display technologies, and in particular, to a display panel, a tiled display panel, and a manufacturing method of display panel.

### BACKGROUND

As a new generation of display technology, micro light-emitting diode display, including Mini-LED and Micro-LED displays, has characteristics of high contrast, long service life, low power consumption, and the like. A display panel usually combines red, green and blue LED chips into one pixel. Then, pixels are disposed on a substrate at a certain space to obtain a display panel. However, differences in luminous efficiency of LED chips with different colors, unequal space between LED chips, and differences in the distance of LED chips from a driving end cause uneven display on the panel display.

### SUMMARY

Embodiments of the present disclosure provides a display panel, a tiled display panel and a manufacturing method of display panel. Light emitted by light-emitting diode (LED) chips is emitted out of a substrate through a plurality of through-holes of a light-shielding layer, and the intensity of the emitted light can be controlled by adjusting sizes of the through-holes corresponding to the LED chips.

In a first aspect, an embodiment of the present disclosure provides a display panel, including: a substrate; a light-shielding layer disposed on the substrate, wherein the light-shielding layer includes a plurality of through-holes; a transparent insulation layer, wherein the transparent insulation layer includes a plurality of transparent portions arranged in the plurality of through-holes respectively; a light-emitting layer disposed on the transparent insulation layer, wherein the light-emitting layer includes a plurality of light-emitting diode (LED) chips are disposed to the plurality of through-holes in a one-to-one correspondence, each of the plurality of LED chips is disposed on a corresponding one of the plurality of transparent portions, and a light-emitting surface the LED chip faces to the transparent portion; a device array layer disposed on the light-shielding layer, wherein the device array layer includes a driver, and a plurality of metal wirings configured to connect the plurality of LED chips with the driver; and a sealing layer disposed on the substrate, wherein the sealing layer encapsulates the light-shielding layer, the transparent insulation layer, the light-emitting layer, and the device array layer.

In some embodiments, the transparent insulation layer further includes an extension portion disposed on the light-shielding layer, the extension portion is integrally formed with the plurality of transparent portions, and the device array layer is disposed on the extension portion.

In some embodiments, the plurality of LED chips includes aa red chip, a green chip, and a blue chip, and the plurality of metal wirings are respectively connected to positive electrodes and negative electrodes of the plurality of LED chip.

In some embodiments, the light-emitting layer includes at least one light-emitting unit group; each light-emitting unit group includes at least one group of pixels, and a sealant encapsulating the at least one group of pixels; and each group of pixels includes a red chip, a green chip and a blue chip.

In some embodiments, positive electrodes or negative electrodes of the plurality of LED chips in each light-emitting unit group shares a same one of the plurality of metal wirings.

In some embodiments, a region on the substrate corresponding to the plurality of through-holes is transparent.

In some embodiments, a transparent adhesive layer is disposed between the light-emitting layer and the transparent insulation layer.

In some embodiments, the light-shielding layer is provided with a plurality of baffles, and each of the plurality of baffles is arranged between adjacent two of the plurality of LED chips.

In a second aspect, the present disclosure provides a tiled display panel, which is formed by tiling any of the display panels mentioned above.

In a third aspect, the present disclosure provides a manufacturing method of a display panel, which includes the following steps: providing a substrate; coating a light-shielding material on the substrate to form a light-shielding layer with a plurality of through-holes; filling a transparent portion in each of the plurality of through-holes to form a transparent insulation layer; providing a LED chip on the transparent portion to form a light-emitting layer, wherein a light-emitting surface of the LED chip faces towards the transparent portion; preparing a plurality of metal wirings on the light-shielding layer to form a device array layer, wherein the plurality of metal wirings is configured to connect the LED chip with a driver; and preparing a sealing layer to encapsulate the light-shielding layer, the transparent insulation layer, the light-emitting layer, and the device array layer.

In some embodiments, before the step of coating a light-shield material on the substrate to form a light-shielding layer with a plurality of through-holes, the method further includes: acquiring luminous parameters and arrangement parameters of the LED chip; and determining a position and a size of the through-hole of the light-shielding layer based on the luminous parameters and the arrangement parameters

According to the display panel, the tiled display panel and the manufacturing method of display panel provided by the embodiments of the present disclosure, the plurality of through-holes is disposed on the light-shielding layer, the LED chips are flipped, and the light-emitting surfaces of the LED chips face towards the through-holes, so that the light emitted by the LED chips is emitted out of the substrate through the through-holes of the light-shielding layer. As such, the intensity of the light emitted from the display panel can be controlled by adjusting the sizes of the through-holes corresponding to the LED chips. In addition, the LED chips are flipped, and the light only needs to pass through the transparent insulation layer and the substrate, which causes less light loss.

### BRIEF DESCRIPTION OF THE DRAWINGS

The following detailed description of specific embodiments of the present disclosure, in conjunction with the accompanying drawings, technical solutions and other beneficial effects of the present disclosure are apparent.

FIG. 1 is a schematic structural diagram of a display panel according to an embodiment of the present disclosure.

FIG. 2 is another schematic structural diagram of a display panel according to an embodiment of the present disclosure;

FIG. 3 is yet another schematic structural diagram of a display panel according to an embodiment of the present disclosure.

FIG. 4 is yet another schematic structural diagram of a display panel according to an embodiment of the present disclosure.

FIG. 5 is yet another schematic structural diagram of a display panel according to an embodiment of the present disclosure.

FIG. 6 is yet another schematic structural diagram of a display panel according to an embodiment of the present disclosure.

### REFERENCE NUMERALS

1. substrate; 2. light-shielding layer; 3. transparent insulation layer; 31. transparent portion; 32. extension portion; 4. light-emitting layer; 41. LED chip; 42. sealant; 43. light-emitting unit group; 5. device array layer; 51. metal wiring; 6. sealing layer; and 7. baffle.

### DETAILED DESCRIPTION OF THE EMBODIMENTS

Technical solutions in embodiments of the present disclosure will be described clearly and completely in conjunction with the accompanying drawings in the embodiments of the present disclosure. Apparently, the described embodiments are only some of applications of the present disclosure, and not all applications. Based on the embodiments in the present disclosure, all other embodiments obtained by those skilled in the art without creative work will fall within the scope of protection of the present disclosure.

In the drawings, the thickness of layers, films, plates, regions, etc., may be enlarged for clarity and for better understanding and easy description. It should be understood that when an element such as a layer, a film, a region, or a substrate is referred to as “disposed on another element”, it may be directly disposed on another element or there may be an inserted element. That is to say, unless otherwise specified and defined, the expression that a first feature is “on” or “under” a second feature may include the first feature and the second feature being in direct contact, or the first feature and the second feature being in contact not directly but through another feature between them.

In addition, unless explicitly described to the contrary, the term “including” and its variants such as “containing” or “having” should be understood as implicitly including the discussed elements, but not necessarily excluding other elements. Further, in the specification, the term “on” refers to be placed above or below a target portion, and does not necessarily mean to be placed on an upper side of the target portion based on the direction of gravity. Moreover, the first feature being “above”, “over” and “on top of” the second feature includes that the first feature is directly above and diagonally above the second feature, or simply indicates that the first feature is horizontally higher than the second feature. The first feature being “under”, “below” and “beneath” the second feature includes that the first feature is directly below and diagonally below the second feature, or simply indicates that the first feature is horizontally smaller in height than the second feature.

It should be understood that although the terms “first”, “second” and the like may be used herein to describe various components, these components should not be limited by these terms. These components are only used to distinguish one component from another.

As used herein, the singular forms “a”, “one” and “the” are also intended to include the plural forms unless the context clearly indicates otherwise.

It should also be understood that the terms “including” and/or “comprising” as used herein specify the presence of the described features or components, but do not preclude the presence or addition of one or more other features or components.

It should be understood that when a layer, a region or a component is said to be “formed” on another layer, region or component, it can be directly or indirectly formed on another layer, region or component. For example, there may be an intermediate layer, an intermediate region or an intermediate component.

In the description of the present disclosure, it should be noted that unless otherwise specified and defined, the terms “installation”, “connected” and “connection” should be broadly understood, for example, they may be fixedly connected, detachably connected, or integrally connected; may be mechanically connected, electrically connected, or capable of communicating with each other; may be directly connected or indirectly connected through an intermediate medium, or may be the internal connection of two elements or the interaction between two elements. For those skilled in the art, the specific meanings of the above terms in the present disclosure can be understood according to the specific circumstances.

The following present disclosure provides many different embodiments or examples for implementing different structures of the present disclosure. In order to simplify the present disclosure, components and arrangements of specific embodiments are described below. Of course, they are only illustrated and are not intended to limit the present disclosure. Furthermore, the present disclosure may repeat reference numerals and/or reference letters in different embodiments, and such repetition is for the purpose of simplicity and clarity, and does not in itself indicate the relationship between the various embodiments and/or arrangements discussed. In addition, the present disclosure provides embodiments of various specific processes and materials, but those skilled in the art can realize the application of other processes and/or the use of other materials.

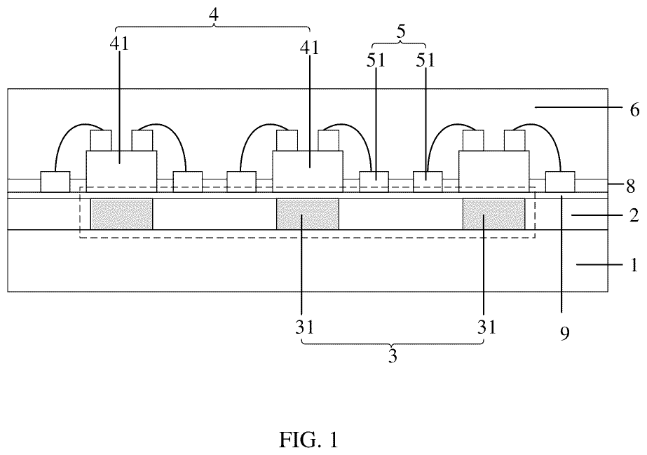

Referring to FIG. 1, an embodiment of the present disclosure provides a display panel, wherein the display panel includes a substrate 1, a light-shielding layer 2, a transparent insulation layer 3, a light-emitting layer 4, a device array layer 5, and a sealing layer 6 arranged sequentially. The substrate 1 is used to support the film layers of various devices mounted thereon.

The light-shielding layer 2 is disposed on the substrate 1, and is provided with a plurality of through-holes. The light-shielding layer 2 is a black matrix (BM), which is a non-transparent structure. Neither the light emitted by the light-emitting layer 4 nor the external natural light can penetrate through the light-shielding layer 2, as such, the light leakage region is shielded to increase the contrast of the display panel. The light-shielding layer 2 may include solder resist ink, but the BM has higher accuracy than the solder resist ink, which can further improve the consistency and contrast of ink color.

The light-emitting layer 4 includes a plurality of light-emitting diode (LED) chips 41, and the LED chips 41 are disposed to the through-holes in a one-to-one correspondence. A light-emitting surface of each of the LED chips 41 faces towards each of the through-holes, that is, the LED chips 41 are flipped disposed. A plurality of through-holes arranged in the light-shielding layer 2 are used for the light of the light-emitting layer 4 to pass through. Therefore, the brightness of the light emitted by each LED chip 41 is accurately controlled by controlling size of each through-hole of the LED chip 41, and then the light emitted by the LED chip 41 is emitted out of the substrate 1. With the LED chips 41 flipped, and the light can only pass through the transparent insulation layer 3 and the substrate 1, resulting in less light loss.

The position of the through-hole coincides with the position of the LED chip 41 in the vertical direction, that is, the LED chip 41 is respectively arranged directly above the through-hole. In order to facilitate the positioning and installation of the LED chip 41, the transparent insulation layer 3 is formed by filling the transparent portion 31 in the through-hole of the light-shielding layer 2, and the LED chip 41 is disposed on the transparent portion 31 to provide the light-emitting surface of the LED chip 41 to face the transparent portion 31. The transparent insulation layer 3 should minimize the influence on the light emitted by the LED chip 41, and the material of the transparent insulation layer 3 may be SiNx or SiOx. It should be noted that, since the intensity of light emitted from the display panel is adjusted by the size of the through-hole, the light-emitting surface of the LED chip 41 is provided greater than or equal to the size of the cross-section of the through-hole. The cross-section of the through-hole refers to a contact surface of the LED chip 41 with the through-hole. That is, when the LED chip 41 is disposed on the transparent portion 31, the area of the LED chip 41 on the contact surface is greater than or equal to the area of the transparent portion 31. That is, the LED chip 41 completely covers the through-hole.

The device array layer 5 is disposed on the light-shielding layer 2, and includes a driver 8 and a plurality of metal wirings 51, and the metal wirings 51 are used to connect the LED chips 41 with the driver 8. The driver 8 may be a thin film transistor (TFT) or an integrated circuit (IC) driver, and the TFT includes but is not limited to several film layers such as a barrier layer, a buffer layer, a gate electrode, a source and drain electrode; and the driver 8 is used to drive and control the opening and closing of the LED chips 41 in the light-emitting layer 4 and the brightness through the metal wirings 51. The sealing layer 6 is disposed on the substrate 1, and encapsulates the light-shielding layer 2, the transparent insulation layer 3, the light-emitting layer 4 and the device array layer 5 for protection.

In an embodiment, the LED chips 41 are flipped, and the light emitted by the LED chip 41 is emitted from the substrate 1 through the through-hole of the light-shielding layer 2. Therefore, the intensity of the emitted light can be controlled by adjusting the size of the through-hole corresponding to the LED chip 41, for example, by increasing the light-emitting area of a red LED chip 41 with low light-emitting efficiency, by increasing the light-emitting area of a LED chip 41 away from the driving end, to regulate the problem of uneven display of the display panel due to differences in luminous efficiency of the LED chips 41 with different colors, unequal space between the LED chips 41, and differences in the distance of the LED chips 41 from the driving end, and the like.

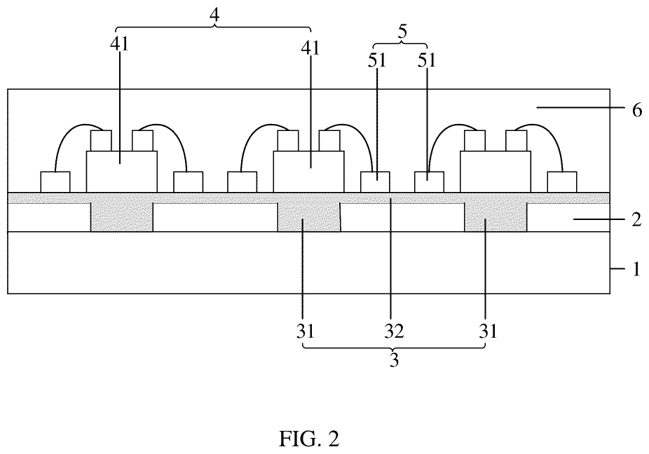

In an embodiment, the transparent insulation layer 3 fills the through-hole of the light-shielding layer 2, which may only fill the through-hole of the light-shielding layer 2 as shown in FIG. 1, or may cover the entire surface of the substrate 1 while filling the through-hole of the light-shielding layer 2 as shown in FIG. 2. As shown in FIG. 2, the transparent insulation layer 3 further includes an extension portion 32 provided on the light-shielding layer 2, which covers the entire surface of the substrate 1. The extension portion 32 is integrally formed with the transparent portion 31, and the device array layer 5 is disposed on the extension portion 32.

In an embodiment, as shown in FIGS. 1 and 2, the LED chips 41 include a red chip, a green chip, and a blue chip, and each LED chip 41 is a separate individual. A positive electrode and a negative electrode of each LED chip 41 are electrically connected to the corresponding one of metal wirings 51, that is, each LED chip 41 is independently controlled.

Due to factors such as differences in luminous efficiency of the LED chips 41 with different colors, unequal space between the LED chips 41, and differences in the distance of the LED chips 41 from the driving end, the sizes of the through-holes corresponding to the LED chips 41 with different colors may be the same or different.

In addition, sizes of through-holes corresponding to LED chips 41 with the same color may be the same or different due to the different positions of the LED chips 41. However, since the arrangement of the LED chips 41 has a certain repeatability, and the corresponding through-holes also have the minimum arrangement unit, all the through-holes on the light-shielding layer 2 can be formed by arranging the arrangement unit including the arrangement (including size and relative position) for the through-holes in an array. The LED chips 41 corresponding to the through-holes in one arrangement unit may be a group of a red chip, a green chip and a blue chip, or may be a plurality of groups. As shown in FIG. 1, the three LED chips 41 corresponding to the three through-holes included in the dashed frame of FIG. 1 are a red chip, a green chip and a blue chip respectively, and the sizes and relative positions of the other red chips, green chips and blue chips in the layer 2 are the same as those of the three LED chips 41 shown in FIG. 1. This is, the three through-holes included in the dashed frame are the minimum arrangement unit of the through-holes. It should be noted that the arrangement of the transparent insulation layer 3 and the arrangement of the LED chips 41 do not affect each other.

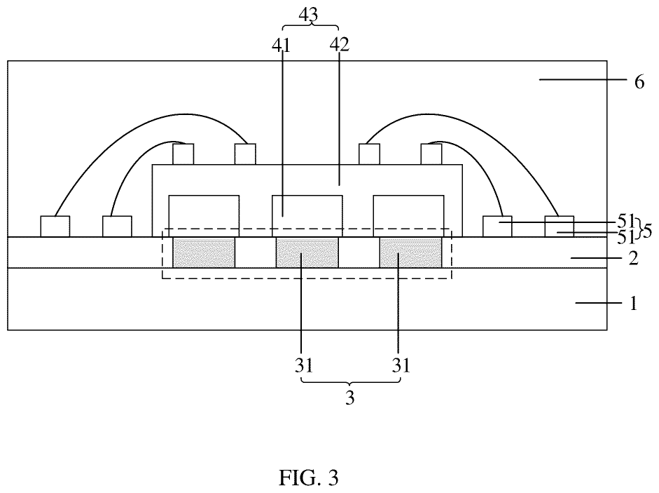

In an embodiment, in order to facilitate the positioning and installation of the LED chips 41, the LED chips 41 with different colors may be assembled into the display panel as a whole. As shown in FIG. 3, the light-emitting layer 4 includes at least one light-emitting unit group 43, and the at least one light-emitting unit group 43 is arranged in an array to form the light-emitting layer 4. Each light-emitting unit group 43 includes at least one group of pixels, and a sealant 42 encapsulating at least one group of pixels. Each group of pixels includes three LED chips 41, for example, a red chip, a green chip and a blue chip. Other structures encapsulating the light-emitting unit group 43 are not described in detail in this embodiment.

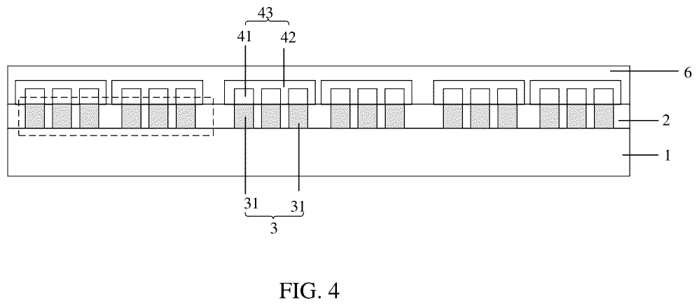

Specifically, in a case that the light-emitting unit groups 43 are arranged in an array to form the light-emitting layer 4, and the arrangement units are arranged in an array to obtain the through-holes of the light-shielding layer 2. The number of LED chips 41 included in the light-emitting unit group 43 may be the same as or different from the number of through-holes in the minimum arrangement unit. As shown in FIG. 3, only one group of pixels is included in the light-emitting unit group 43, that is, one light-emitting unit group 43 includes a red chip, a green chip and a blue chip, three LED chips 41 in total, and a plurality of light-emitting unit groups 43 are arranged in an array sequentially, and three through-holes corresponding to light-emitting unit groups 43 are also arranged in an array. In this situation, the three through-holes included in the dashed frame shown in FIG. 3 define the minimum arrangement unit, and the number of LED chips 41 included in the light-emitting unit group 43 is the same as the number of the through-holes in the minimum arrangement unit. However, as shown in FIG. 4, in the light-emitting layer 4, the minimum unit array is defined as whole by two light-emitting unit groups 43. As shown in the dashed frame in FIG. 4, the minimum arrangement unit of through-holes includes six through-holes corresponding to the two light-emitting unit groups 43. In this situation, the number of LED chips 41 included in the light-emitting unit group 43 is different from the number of through-holes in the minimum arrangement unit. It should be noted that the light-emitting layer 4 may also include a plurality of different light-emitting unit groups 43, but each light-emitting unit group 43 includes at least one group of pixels and a sealant 42 encapsulating at least one group of pixels.

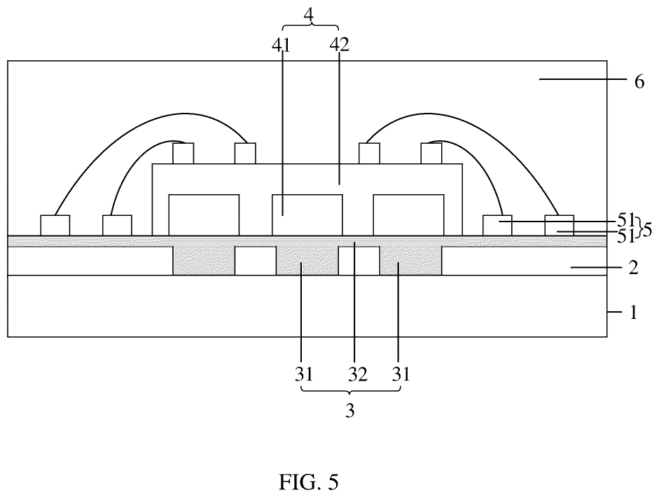

In an embodiment, ones of the positive electrodes and the negative electrodes of the LED chips 41 in each light emitting unit group 43 share the same metal wiring 51, and the other ones of the positive electrodes and the negative electrodes of the LED chips 41 are individually connected to another metal wiring 51. As shown in FIGS. 3 and 5, each light-emitting unit group 43 includes a group of pixels, that is, each light-emitting unit group 43 includes a red chip, a green chip and a blue chip. In the light-emitting unit group 43 shown in FIG. 3, ends of the ones of the positive electrodes and the negative electrodes of the LED chips 41 are independently connected with different metal wirings 51, and ends of the other ones of the positive electrodes and the negative electrodes share the same metal wiring 51, that is, each light-emitting unit group 43 is connected with four metal wirings 51.

In an embodiment, each LED chip 41 is flipped, the light-emitting surface of each LED chip 41 faces towards the through-hole, and the light emitted from the LED chip 41 is emitted after passing through the transparent insulation layer 3 and the substrate 1. In order to reduce the light loss, a transparent region is arranged in a region of the substrate corresponding to the through-hole, that is, no functional film is arranged in the region where the light emitted by the LED chip 41 passes through the substrate 1.

That is to say, along the vertical direction of the light-emitting surface of the LED chip 41, the portion of the substrate 1 in the orthographic projection of the through-hole on the substrate 1, and the transparent portion 31 in the through-hole of the light-shielding layer 2 are transparent regions. As such, no film structure to be affected by the light is provided to reduce the light loss. It should be noted that, due to the certain diffusion effect of the light, the range of the transparent region on the substrate 1 is greater than the orthographic projection of the corresponding through-hole on the substrate 1, along the vertical direction of the light-emitting surface of the LED chip 41.

In an embodiment, with each LED chip 41 flipped, in order to facilitate the positioning and fixing of the LED chip 41, a transparent adhesive layer 9 is provided between the light-emitting layer 4 and the transparent insulation layer 3. For example, each LED chip 41 is fixed on the transparent insulation layer 3 by transparent solder paste, and then the positive electrode and the negative electrode of each LED chip 41 are soldered with the corresponding metal wirings 51. Since the positive electrodes or the negative electrodes of the LED chips 41 in the packaged light-emitting unit group 43 may share the same metal wiring 51, in order to avoid affecting the signal wiring of the LED chips 41 in the same light-emitting unit group 43, the transparent adhesive layer 9 is made of insulation material.

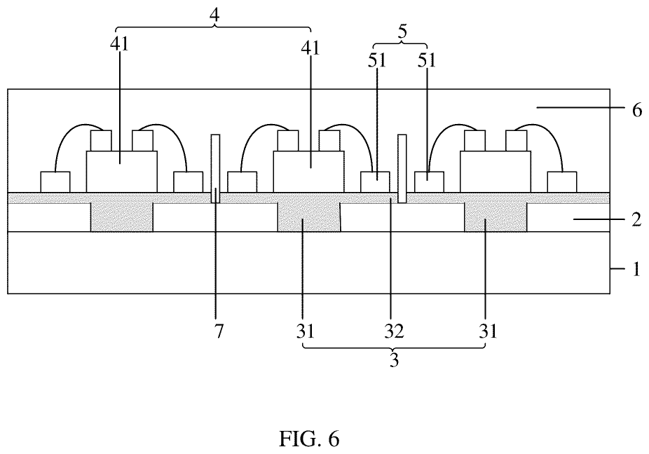

In an embodiment, the transparent insulation layer 3 further includes an extension portion 32 formed integrally with the transparent portions 31 on the light-shielding layer 2, and the extension portion 32 covers the entire surface of the substrate 1, as shown in FIG. 6. In order to avoid crosstalk between adjacent LED chips 41, a plurality of baffles 7 are disposed on the light-shielding layer 2, and the baffles 7 are arranged between adjacent LED chips 41. The baffle 7 and the light-shielding layer 2 may be formed integrally in the same process, or may be two separate structures.

When the baffles 7 are provided on the light-shielding layer 2, the transparent insulation layer 3 may only include the transparent portions 31 filled in the through-holes of the light-shielding layer 2, or both the transparent portions 31 filled in the through-holes of the light-shielding layer 2 and the extension portion 32 covering the non-baffle region, or both the transparent portions 31 filled the through-holes of the light-shielding layer 2 and the extension portion 32 covering the baffle 7 and the light-shielding layer 2.

In an embodiment, with the LED chips 41 flipped, and the light emitted by the LED chip 41 is emitted from the substrate 1 through the through-hole of the light-shielding layer 2. Therefore, the intensity of the emitted light can be controlled by adjusting the size of the through-hole corresponding to the LED chip 41, such as by increasing the light-emitting area of the red LED chip 41 with low light-emitting efficiency, and increasing the light-emitting area of the LED chip 41 away from the driving end, to regulate the problem of uneven display of the display panel due to differences in luminous efficiency of the LED chips 41 with different colors, unequal space between the LED chips 41, and differences in the distance of the LED chips 41 from the driving end, etc.

Another embodiment of the present disclosure provides a manufacturing method of display panel. The manufacturing method includes: S10, providing a substrate; S20, coating a light-shielding material on the substrate to form a light-shielding layer with a plurality of through-holes; S30, filling a transparent portion in each of the plurality of through-holes to form a transparent insulation layer; S40, providing a LED chip on the transparent portion to form a light-emitting layer, with a light-emitting surface of the LED chip facing towards the transparent portion; S50, preparing a plurality of metal wirings on the light-shielding layer to form a device array layer, wherein the plurality of metal wirings is configured to connect the LED chip with a driver; and S60: preparing a sealing layer to encapsulate the light-shielding layer, the transparent insulation layer, the light-emitting layer, and the device array layer.

Specifically, as shown in FIG. 1 to FIG. 6, the substrate 1 is provided, the light-shielding material is coated on the substrate 1, and a plurality of through-holes are etched on the light-shielding material to form the light-shielding layer 2. Since the light is emitted through the through-holes of the light-shielding layer 2 and the part of the substrate 1 corresponding to the through-holes, during preparing the substrate 1, the substrate 1 is provided with a transparent region corresponding to the through-holes, and no other functional film layer is provided in the transparent region.

The transparent insulation layer 3 is formed by filling the transparent portion 31 in each through-hole. In some embodiments, an extension portion 32 may be provided on the light-shielding layer 2, and the extension portion 32 is integrally formed with the transparent portion 31 to form the transparent insulation layer 3. The LED chip 41 is disposed on the transparent portion 31 to form the light-emitting layer 4. In order to facilitate the positioning and fixing of the LED chip 41, a transparent adhesive layer 9 is arranged between the light-emitting layer 4 and the transparent insulation layer 3, and the LED chip 41 is fixed on the transparent insulation layer 3 by transparent solder paste, for example. With the LED chips 41 flipped, the light-emitting surface of the LED chip 41 face towards the through-hole, so the light emitted by the LED chip 41 is emitted from the substrate 1 through the through-hole of the light-shielding layer 2. As such, the light only needs to pass through the transparent insulation layer 3 and the substrate 1, resulting in less light loss. In order to avoid crosstalk between adjacent LED chips 41 with different colors, a baffle 7 may be provided on the light-shielding layer 2.

The LED chips 41 included in the light-emitting layer 4 may be independent light-emitting chips with different colors, and the positive electrode and the negative electrode of each LED chip 41 are respectively connected to metal wirings 51. The LED chips 41 included in the light-emitting layer 4 may be packaged into light-emitting unit groups, each light-emitting unit group includes at least one group of pixels and a sealant 42 encapsulating at least one group of pixels. Each group of pixels includes a red chip, a green chip and a blue chip, and the ones of the positive electrodes and the negative electrodes of the LED chips 41 in the light-emitting unit group share the same metal wiring 51. The driver 8 and the plurality of metal wirings 51 form the device array layer 5, and the metal wirings 51 are used to connect the LED chips 41 with the driver 8, and the driver 8 drives and controls the opening and closing of the LED chips 41 and brightness through the metal wirings 51. Finally, the sealing layer 6 is prepared to encapsulate the light-shielding layer 2, the transparent insulation layer 3, the light-emitting layer 4 and the device array layer 5 for protection.

In an embodiment, before the step S20 of the coating the light-shield material on the substrate to form the light-shielding layer with the plurality of through-holes, the method further includes: S70, acquiring luminous parameters and arrangement parameters of the LED chip; and S80, determining a position and a size of the through-hole of the light-shielding layer based on the luminous parameters and the arrangement parameters.

Specifically, the differences in luminous efficiency of the LED chips 41 with different colors, unequal space between the LED chips 41, and differences in the distance of the LED chips 41 from the driving end, etc., cause the problem of uneven display of the display panel. According to the present disclosure, the luminous parameters of LED chips 41 with different colors are obtained, including but not limited to luminous efficiency, and the arrangement parameters of LED chips 41, such as the relative positions of LED chips 41 with respect to each other and the distances from the driving end, are obtained.

Based on the luminous parameters and arrangement parameters, the position and size of the through-hole in the light-shielding layer 2 are determined, and the LED chip 41 is arranged above the through-hole, so that the position of the through-hole is the position where the LED chip 41 is placed. In addition, the intensity of the light emitted from the display panel can be controlled by adjusting the size of the through-hole corresponding to the LED chip 41, that is, the uneven display of different LED chips 41 can be balanced by adjusting the sizes of different through-holes. The relationship between the luminous parameters and arrangement parameters of the LED chip 41 and the size of the through-hole can be obtained through test calibration, so as to be used by looking up the table when determining the size of the through-hole.

The present disclosure provides a tiled display panel, which is formed by tiling the display panel described in any of the above embodiments.

In the above-mentioned embodiments, the description of each embodiment has its own focus, and parts of an embodiment that are not described in detail can be found in the relevant descriptions of other embodiments.

The technical features of the above embodiments can be combined arbitrarily, and all possible combinations of the technical features in the above embodiments are not described for the sake of conciseness of description. However, as long as there is no contradiction in the combinations of these technical features, they should be considered to be within the scope of this specification.

The display panel, the tiled display panel and the manufacturing method of display panel provided by the embodiments of the present disclosure are described in detail above. The principle and implementation of the present disclosure are illustrated by way of specific embodiments, and the description of the above embodiments is only intended to facilitate an understanding of the method and core concept of the present disclosure. For those skilled in the art, according to the idea of the present disclosure, there will be changes in the specific implementation and application scope. The contents of this specification should not be understood as the limitation the present disclosure.

What is claimed is:

1. A display panel, comprising:
a substrate;
a light-shielding layer disposed on the substrate, wherein the light-shielding layer comprises a plurality of through-holes;
a transparent insulation layer, wherein the transparent insulation layer comprises a plurality of transparent portions arranged in the plurality of through-holes respectively;
a light-emitting layer disposed on the transparent insulation layer, wherein the light-emitting layer comprises a plurality of light-emitting diode (LED) chips are disposed to the plurality of through-holes in a one-to-one correspondence, each of the plurality of LED chips is disposed on a corresponding one of the plurality of transparent portions, and a light-emitting surface the LED chip faces to the transparent portion;
a device array layer disposed on the light-shielding layer, wherein the device array layer comprises a driver, and a plurality of metal wirings configured to connect the plurality of LED chips with the driver; and
a sealing layer disposed on the substrate, wherein the sealing layer encapsulates the light-shielding layer, the transparent insulation layer, the light-emitting layer, and the device array layer.

2. The display panel of claim 1, wherein the transparent insulation layer further comprises an extension portion disposed on the light-shielding layer, the extension portion is integrally formed with the plurality of transparent portions, and the device array layer is disposed on the extension portion.

3. The display panel of claim 1, wherein the plurality of LED chips comprises a red chip, a green chip, and a blue chip, and the plurality of metal wirings are respectively connected to positive electrodes and negative electrodes of the plurality of LED chips.

4. The display panel of claim 1, wherein the light-emitting layer comprises at least one light-emitting unit group; each light-emitting unit group comprises at least one group of pixels, and a sealant encapsulating the at least one group of pixels; and each group of pixels comprises a red chip, a green chip and a blue chip.

5. The display panel of claim 4, wherein positive electrodes or negative electrodes of the plurality of LED chips in each light-emitting unit group shares a same one of the plurality of metal wirings.

6. The display panel of claim 1, wherein a region on the substrate corresponding to the plurality of through-holes is transparent.

7. The display panel of claim 1, wherein a transparent adhesive layer is disposed between the light-emitting layer and the transparent insulation layer.

8. The display panel of claim 1, wherein the light-shielding layer is provided with a plurality of baffles, and each of the plurality of baffles is arranged between adjacent two of the plurality of LED chips.

9. A tiled display panel, wherein the tiled display panel is formed by tiling the display panels of claim 1.

10. The tiled display panel of claim 9, wherein the transparent insulation layer further comprises an extension portion disposed on the light-shielding layer, the extension portion is integrally formed with the plurality of transparent portions, and the device array layer is disposed on the extension portion.

11. The tiled display panel of claim 9, wherein the plurality of LED chips comprises a red chip, a green chip, and a blue chip, and the plurality of metal wirings are respectively connected to positive electrodes and negative electrodes of the plurality of LED chips.

12. The tiled display panel of claim 9, wherein the light-emitting layer comprises at least one light-emitting unit group; each light-emitting unit group comprises at least one group of pixels, and a sealant encapsulating the at least one group of pixels; and each group of pixels comprises a red chip, a green chip and a blue chip.

13. The tiled display panel of claim 12, wherein positive electrodes or negative electrodes of the plurality of LED chips in each light-emitting unit group shares a same one of the plurality of metal wirings.

14. The tiled display panel of claim 9, wherein a region on the substrate corresponding to the plurality of through-holes is transparent.

15. The tiled display panel of claim 9, wherein a transparent adhesive layer is disposed between the light-emitting layer and the transparent insulation layer.

16. The tiled display panel of claim 9, wherein the light-shielding layer is provided with a plurality of baffles, and each of the plurality of baffles is arranged between adjacent two of the plurality of LED chips.

17. A manufacturing method of a display panel, comprising:
providing a substrate;
coating a light-shielding material on the substrate to form a light-shielding layer with a plurality of through-holes;
filling a transparent portion in each of the plurality of through-holes to form a transparent insulation layer;
providing a LED chip on the transparent portion to form a light-emitting layer, wherein a light-emitting surface of the LED chip faces towards the transparent portion;
preparing a plurality of metal wirings on the light-shielding layer to form a device array layer, wherein the plurality of metal wirings is configured to connect the LED chip with a driver; and
preparing a sealing layer to encapsulate the light-shielding layer, the transparent insulation layer, the light-emitting layer, and the device array layer.

18. The manufacturing method of claim 16, wherein the coating the light-shield material on the substrate to form the light-shielding layer with the plurality of through-holes, the method further comprises: acquiring luminous parameters and arrangement parameters of the LED chip; and determining a position and a size of the through-hole of the light-shielding layer based on the luminous parameters and the arrangement parameters.
